(19) United States
(12) Patent Application Publication
(10) Pub. No.: US 2017/0261568 A1
(43) Pub. Date: Sep. 14, 2017

(54) SEMICONDUCTOR DEVICE AND MAGNETIC SENSOR

(71) Applicant: KABUSHIKI KAISHA TOSHIBA, Tokyo (JP)

(72) Inventor: Hideaki MIYOSHI, Kawasaki Kanagawa (JP)

(21) Appl. No.: 15/239,608

(22) Filed: Aug. 17, 2016

(30) Foreign Application Priority Data
Mar. 11, 2016 (JP) 2016-048707

(51) Int. Cl. G01R 33/07; H01L 43/06

(52) U.S. Cl. CPC G01R 33/072; H01L 43/065

(57) ABSTRACT

A semiconductor device includes a voltage-current converter configured to output an output current in response to a control voltage and a Hall element configured to output a voltage signal according to the output current from the voltage-current converter and a magnetic flux density of a magnetic field applied to the Hall element. An amplifier is configured to amplify the voltage signal from the Hall element. And a terminal is connected to the amplifier. At the terminal the gain of the amplifier can be adjusted by connecting an impedance element.

### CROSS-REFERENCE TO RELATED APPLICATION

This application is based upon and claims the benefit of priority from Japanese Patent Application No. 2016-048707, filed Mar. 11, 2016, the entire contents of which are incorporated herein by reference.

### FIELD

Embodiments described herein relate generally to a semiconductor device and a magnetic sensor.

### BACKGROUND

Generally, in products including a magnetic sensor in which a Hall element is used, the required magnetic sensitivity is uniquely determined according to the product requirements, and thus it is necessary to research the magnetic sensitivity of each product beforehand and then select a sensor in which a desired magnetic sensitivity can be obtained. That is, the magnetic sensitivity of any particular magnetic sensor incorporated into a product is predetermined and it is not possible for a user or product designer to adjust or change the sensitivity of the particular magnetic sensor once it has been selected. Therefore, product developers need to develop a plurality of products in which magnetic sensors may have different magnetic sensitivity, and this is costly. The designer also needs to carefully select a product having an optimum magnetic sensitivity for various purposes, and the time and effort for making such a selection may be large.

### DESCRIPTION OF THE DRAWINGS

FIG. 1 is a block diagram of a magnetic sensor of a first embodiment.

FIG. 2 is a circuit diagram illustrating an example of an internal configuration of a voltage-current converter of FIG. 1.

FIG. 3 is a circuit diagram illustrating an example of an internal configuration of an amplifier of FIG. 1.

FIG. 4A is a graph illustrating a correspondence relationship between a magnetic flux density and an output voltage of a magnetic sensor when a resistance value of a resistance element is varied.

FIG. 4B is a graph illustrating a correspondence relationship between the magnetic flux density and the output voltage of the magnetic sensor when a control voltage is varied.

FIG. 5 is a block diagram of a magnetic sensor according to a second embodiment.

FIG. 6A is a graph illustrating a correspondence relationship between a magnetic flux density and an output voltage of a magnetic sensor when a resistance value of a resistance element is varied.

FIG. 6B is a graph illustrating a correspondence relationship between the magnetic flux density and an output voltage of a magnetic sensor when a control voltage is varied.

### DETAILED DESCRIPTION

In general, according to one embodiment, a semiconductor device includes a voltage-current converter configured to output an output current in response to a control voltage and a Hall element configured to output a voltage signal according to the output current from the voltage-current converter and a magnetic flux density of a magnetic field applied to the Hall element. An amplifier is configured to amplify the voltage signal from the Hall element. And a terminal is connected to the amplifier. At the terminal a gain of the amplifier can be adjusted by connection of an impedance element to the terminal.

Hereinafter, example embodiments will be described with reference to drawings.

### First Embodiment

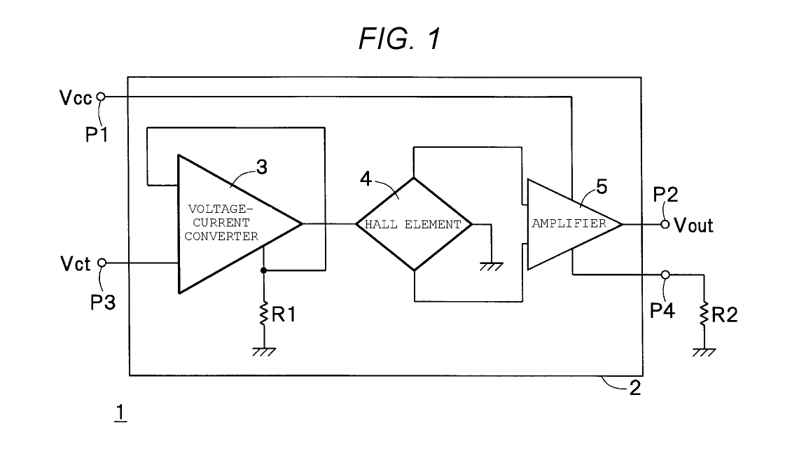

FIG. 1 is a block diagram of a magnetic sensor 1 according to a first embodiment. The magnetic sensor 1 in FIG. 1 includes a semiconductor device 2 and the resistance element R2. The semiconductor device 2 is an integrated circuit (IC) chip which includes a voltage-current converter 3, a resistance element R1, a Hall element 4, an amplifier (Amp) 5, a power source voltage terminal P1, an output terminal P2, a control voltage terminal P3, and an adjustment terminal P4. The semiconductor device 2 is driven by a power source voltage Vcc applied to the power source voltage terminal P1.

The control voltage terminal P3 is connected to the voltage-current converter 3. The voltage-current converter 3 generates and outputs an output current according to a control voltage Vct supplied to the control voltage terminal P3. The resistance element R1 is connected to the voltage-current converter 3. The voltage-current converter 3 outputs the output current according to the control voltage Vct and a voltage difference across the resistance element R1.

The Hall element 4 outputs a voltage signal that is generated by the output current of the voltage-current converter 3 and the magnetic flux density of the magnetic field around the Hall element 4. In more detail, a Lorentz force is generated by the output current of the voltage-current converter 3 and the magnetic flux density of the magnetic field, and carriers are moved and an electric field is generated by the Lorentz force. The Hall element 4 outputs the voltage signal by the electric field.

The amplifier 5 amplifies and outputs the voltage signal output from the Hall element 4. The output signal of the amplifier 5 becomes an output signal Vout of the magnetic sensor 1. The gain of the amplifier 5 is adjustable by changing the resistance value (impedance) of the resistance element R2 connected to the adjustment terminal P4.

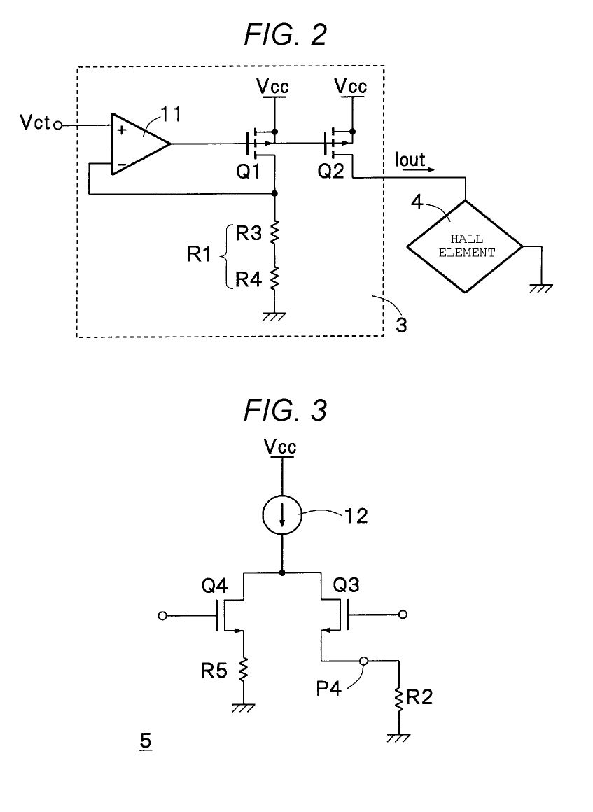

FIG. 2 is a circuit diagram illustrating an example of an internal configuration of the voltage-current converter 3 of FIG. 1. The voltage-current converter 3 depicted in FIG. 2 includes a differential amplifier 11, a PMOS transistor Q1, a resistance element R3, a resistance element R4, and a PMOS transistor Q2.

A source of the PMOS transistor Q1 is connected to a power source voltage node Vcc, and a gate of PMOS transistor Q1 is connected to an output node of the differential amplifier 11. The resistance element R3 and the resistance element R4 are connected in series between a drain of the PMOS transistor Q1 and a ground node. The resistance element R3 and the resistance element R4 together correspond to the resistance element R1 of FIG. 1. The resistance element R3 can be a diffusion resistor formed in an N-type well region, and the resistance element R4 can be a polysilicon resistor. The temperature (thermal) characteristics of the resistance element R3 and the resistance element R4 are reversed (opposed) to one another, thus the temperature characteristics can offset against each other. Accordingly, the resistance value of the resistance element R1 provided by combining the resistance elements R3 and R4 will not have a substantial temperature dependence. Moreover, if the temperature varying characteristics are not considered a problem, the resistance elements R3 and R4 in FIG. 2 may instead be configured as one resistance element R1.

The differential amplifier 11 outputs a signal according to a voltage difference between the control voltage Vct (supplied to the control voltage terminal P3) and a drain voltage of the PMOS transistor Q1. The output signal of the differential amplifier 11 is supplied to a gate of the PMOS transistor Q1 and a gate of the PMOS transistor Q2. Therefore, in response to the output signal of the differential amplifier 11 current flows between the source and the drain of the PMOS transistor Q2. The current is supplied to the Hall element 4.

If the Hall element 4 is disposed in a magnetic field, the Hall element 4 outputs a voltage signal in response to the magnetic flux density of the magnetic field and the output current from the voltage-current converter 3. The voltage signal output from the Hall element 4 is increased as the magnetic flux density and/or the output current of the voltage-current converter 3 is increased.

The amplifier 5 of FIG. 1 amplifies and outputs the voltage signal output from the Hall element 4 with a gain according to the resistance value of the resistance element R2 connected to the adjustment terminal P4.

FIG. 3 is a circuit diagram illustrating an example of the internal configuration of the amplifier 5 of FIG. 1. The amplifier 5 depicted in FIG. 3 includes an NMOS transistor Q3, an NMOS transistor Q4, a current source 12 connected between the power source voltage node Vcc and drains of these transistors Q3 and Q4, the resistance element R2 connected between a source of the NMOS transistor Q3 and the ground node, and a resistance element R5 connected between the source of the NMOS transistor Q4 and the ground node.

The resistance element R2 (connected to the source of the NMOS transistor Q3) is the resistance element R2 connected to the adjustment terminal P4 in FIG. 1, and is an external resistance, for example. The source of the NMOS transistor Q3 is connected to the resistance element R2 through the adjustment terminal P4. As described above, the resistance element R2 can be set to be an arbitrary resistance value.

In contrast thereto, the resistance element R5 is a fixed resistance value. When the resistance value of the resistance element R2 is adjusted, the gain of the amplifier 5 can be adjusted. Since the gain of the amplifier 5 can be adjusted, it means that the output voltage of the magnetic sensor 1 can be adjusted. The resistance element R2 connected to the adjustment terminal P4 can be used to coarsely adjust the magnetic sensitivity of the magnetic sensor 1.

Meanwhile, if the control voltage Vct supplied to the control voltage terminal P3 is changed, a voltage level of the output signal of the differential amplifier 11 is changed, and thus current flowing between the source and the drain of the PMOS transistor Q2 of FIG. 2 changes. Accordingly, when the control voltage Vct supplied to the control voltage terminal P3 is changed, the current flowing (Iout) to the Hall element 4 can be adjusted. The control voltage Vct supplied to the control voltage terminal P3 can be used to finely adjust the magnetic sensitivity of the magnetic sensor 1.

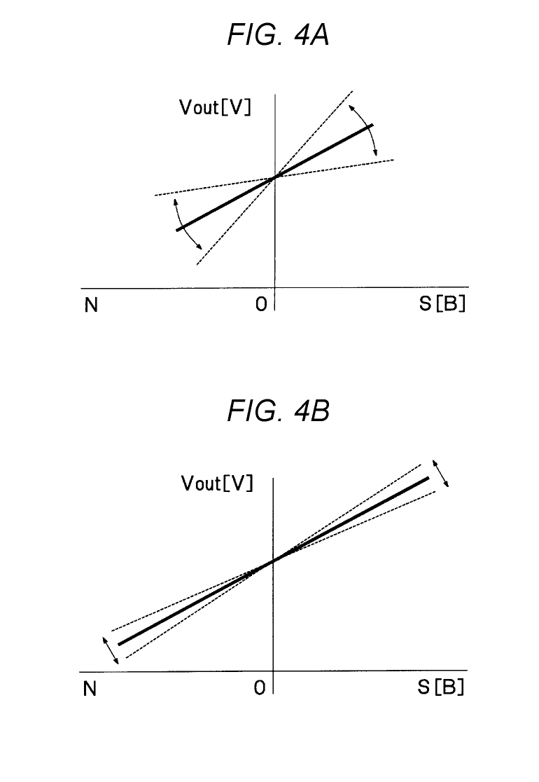

FIG. 4A is a graph illustrating a correspondence relationship between the magnetic flux density and the output voltage of the magnetic sensor 1 when the resistance value of the resistance element R2 connected to the adjustment terminal P4 is changed. FIG. 4B is a graph illustrating a correspondence relationship between the magnetic flux density and the output voltage of the magnetic sensor 1 when the control voltage Vct supplied to the control voltage terminal P3 is changed. A horizontal axis of FIG. 4A and FIG. 4B is a magnetic flux density [B], and a vertical axis is an output voltage [V] (Vout) of the magnetic sensor 1.

As seen from FIG. 4A, when the resistance value of the resistance element R2 connected to the adjustment terminal P4 is changed, the output voltage of the magnetic sensor 1 can be changed greatly. As seen from FIG. 4B, even when the control voltage Vct supplied to the control voltage terminal P3 is changed, the output voltage of the magnetic sensor 1 is not changed very much. Accordingly, to adjust the magnetic sensitivity of the magnetic sensor 1, the resistance value of the resistance element R2 connected to the adjustment terminal P4 is first set to a resistance value at which a desired magnetic sensitivity can be ultimately obtained—that is, the magnetic sensitivity is coarsely adjusted to a level from which adjustments to the control voltage Vct (supplied to the control voltage terminal P3) can be used to provide the specifically desired magnetic sensitivity. The changes in control voltage Vct level is used to finely adjust the magnetic sensitivity to the desired value. Accordingly, the magnetic sensitivity of magnetic sensor 1 can be accurately adjusted within a wide range.

The resistance element R2 may be attached to the outside of the semiconductor device 2, and a user can arbitrarily set the resistance value by connecting different resistors or the like to the adjustment terminal P4. In addition, in some embodiments, a variable resistor could be used as the resistance element R2. In this case, even after mounting the semiconductor device 2 and the resistance element R2, a user can set an optimum resistance value while measuring the magnetic sensitivity. Thus, a process for optimizing the magnetic sensitivity of the magnetic sensor 1 can be more readily performed.

As seen from the above, in the first embodiment, the adjustment terminal P4 and the control voltage terminal P3 are provided on the semiconductor device 2, and the resistance value of the resistance element R2 connected to the adjustment terminal P4 is adjusted, so that the magnetic sensitivity of the magnetic sensor 1 can be coarsely adjusted. In addition, when the control voltage Vct supplied to the control voltage terminal P3 is adjusted, the magnetic sensitivity of the magnetic sensor 1 can be finely adjusted. Therefore, according to the first embodiment, the magnetic sensitivity of magnetic sensor 1 can be adjusted within a wide range, and utility the magnetic sensor 1 can be increased.

### Second Embodiment

In the first embodiment described above, an example of the magnetic sensor 1 having a linear output, in which an output voltage is output in response to the magnetic flux density of the magnetic field, has been described; however, in the magnetic sensor 10 according to a second embodiment a digital output is provided.

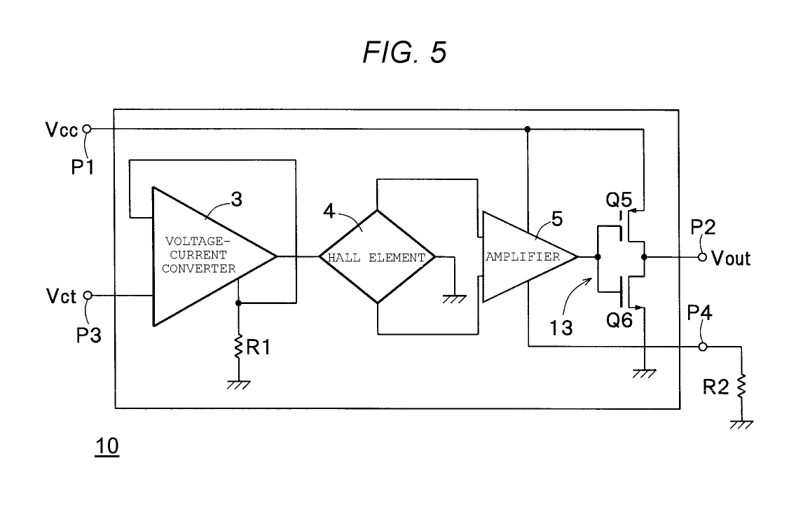

FIG. 5 is a block diagram of the magnetic sensor 10 according to the second embodiment. In FIG. 5, the same reference numerals are given to configuration parts common to the first and second embodiments, and differences will be mainly described hereinafter. The magnetic sensor 10 of FIG. 5 is provided with a hysteresis circuit 13 in addition to the configuration parts of magnetic sensor 1. The hysteresis circuit 13 is connected to an output side of the amplifier 5. The hysteresis circuit 13 includes a PMOS transistor Q5 and an NMOS transistor Q6, which are connected between the power source voltage node Vcc and the ground node. Gates of the PMOS transistor Q5 and the NMOS transistor Q6 are connected to an output node of the amplifier 5. The drain of the PMOS transistor Q5 and the drain of the NMOS transistor Q6 are connected to the output terminal P2 of the magnetic sensor 10. A threshold voltage of the PMOS transistor Q5 and a threshold voltage of the NMOS transistor Q6 are different from each other, and therefore, the hysteresis characteristic is provided.

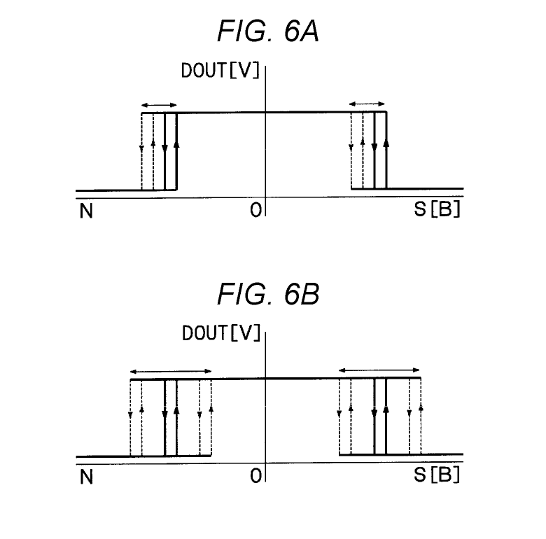

FIG. 6A is a graph illustrating a relationship between a magnetic flux density and the output voltage DOUT from the magnetic sensor 10, when the resistance value of the resistance element R2 connected to the adjustment terminal P4 is varied. FIG. 6B is a graph illustrating a relationship between a magnetic flux density and the output voltage DOUT of the magnetic sensor 10, when the control voltage Vct supplied to the control voltage terminal P3 is varied. Horizontal axes in FIG. 6A and FIG. 6B are a magnetic flux density [B], and vertical axes thereof are an output voltage [V] of the magnetic sensor 10. Arrows in FIG. 6A and FIG. 6B indicate an adjustment range of the magnetic sensitivity.

As seen from FIG. 6A and FIG. 6B, even if the magnetic sensor 10 outputs a digital signal DOUT, the resistance value of the resistance element R2 that is connected to the adjustment terminal P4 can be varied, and thus the magnetic sensitivity can be coarsely adjusted accordingly. In addition, when the voltage of the control voltage Vct supplied to the control voltage terminal P3 is varied, the magnetic sensitivity can be finely adjusted.

While certain embodiments have been described, these embodiments have been presented by way of example only, and are not intended to limit the scope of the present disclosure. Indeed, the novel embodiments described herein may be embodied in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure.

What is claimed is:

1. A semiconductor device, comprising:
a voltage-current converter configured to output an output current in response to a control voltage;
a Hall element configured to output a voltage signal according to the output current from the voltage-current converter and a magnetic flux density of a magnetic field applied to the Hall element;
an amplifier configured to amplify the voltage signal from the Hall element; and
a terminal connected to the amplifier at which a gain of the amplifier can be adjusted by connection of an impedance element to the terminal.

2. The semiconductor device according to claim 1, wherein the impedance element is a resistor.

3. The semiconductor device according to claim 1, further comprising:
a hysteresis circuit connected to an output of the amplifier circuit and configured to binarize the voltage signal from the amplifier.

4. The semiconductor device according to claim 3, wherein
the hysteresis circuit comprises a first transistor connected in series with a second transistor between a first voltage terminal and a ground terminal,
gates of the first and second transistors are connected to an output of the amplifier,
the first and second transistors have different threshold voltages, and
an output voltage terminal is connected to a node between the first and second transistors.

5. The semiconductor device according to claim 4, wherein
the first transistor is a PMOS-type transistor, and
the second transistor is a NMOS-type transistor.

6. The semiconductor device according to claim 1, wherein the voltage-current converter circuit comprises:
a differential amplifier receiving the control signal at a first input terminal;
a first transistor having a gate connected to an output terminal of the differential amplifier, a drain connected to a second input terminal of the differential amplifier, and a source connected to a first voltage terminal;
a first resistance element connected between the drain of the first transistor and a ground node; and
a second transistor having a gate connected to the output terminal of the differential amplifier, a drain to the Hall element, and a source connected to the first voltage terminal.

7. The semiconductor device according to claim 6, wherein the first resistance element comprises a first resistor and a second resistor.

8. The semiconductor device according to claim 7, wherein the first resistor and the second resistor have opposed thermal characteristics.

9. The semiconductor device according to claim 7, wherein the first resistor is a diffusion resistor and the second resistor is a polysilicon resistor.

10. The semiconductor device according to claim 1, wherein the voltage signal from the Hall element increases as the magnetic flux density applied thereto increases.

11. A magnetic sensor, comprising:
a voltage-current converter configured to output an output current in response to a control voltage;
a Hall element configured to output a voltage signal according to the output current and a magnetic flux density of a magnetic field applied to the Hall element;
an amplifier configured to amplify the voltage signal from the Hall element;
a terminal connected to the amplifier at which a gain of the amplifier can be adjusted by connection of an impedance element to the terminal; and
an impedance element connected to the terminal.

12. The magnetic sensor according to claim 11, wherein the impedance element connected to the terminal is a resistor.

13. The magnetic sensor according to claim 11, further comprising:
a hysteresis circuit connected to an output of the amplifier circuit and configured to binarize the voltage signal from the amplifier.

14. The magnetic sensor according to claim 13, wherein
the hysteresis circuit comprises a first transistor connected in series with a second transistor between a first voltage terminal and a ground terminal,
gates of the first and second transistors are connected to an output of the amplifier,
the first and second transistors have different threshold voltages, and
an output voltage terminal is connected to a node between the first and second transistors.

15. The magnetic sensor according to claim 14, wherein the first transistor is a PMOS-type transistor and the second transistor is a NMOS-type transistor.

16. The magnetic sensor according to claim 11, wherein the voltage-current converter circuit comprises:
a differential amplifier receiving the control signal at a first input terminal;
a first transistor having a gate connected to an output terminal of the differential amplifier, a drain connected to a second input terminal of the differential amplifier, and a source connected to a first voltage terminal;
a first resistance element connected between the drain of the first transistor and a ground node; and
a second transistor having a gate connected to the output terminal of the differential amplifier, a drain connected to the Hall element, and a source connected to the first voltage terminal.

17. The magnetic sensor according to claim 16, wherein the first resistance element comprises a first resistor and a second resistor.

18. The magnetic sensor according to claim 17, wherein the first resistor and the second resistor have opposed thermal characteristics.

19. A semiconductor device, comprising:
a Hall element having an input node and an output node and configured to output a voltage signal from the output node according to a first current supplied to the input node and a magnetic flux density of a magnetic field applied to the Hall element;
a differential amplifier receiving a control signal at a first input terminal;
a first transistor having a gate connected to an output terminal of the differential amplifier, a drain connected to a second input terminal of the differential amplifier, and a source connected to a first voltage terminal;
a first resistance element connected between the drain of the first transistor and a ground node;
a second transistor having a gate connected to the output terminal of the differential amplifier, a drain connected to the input node of the Hall element, and a source connected to the first voltage terminal;
a third transistor having a gate connected to a voltage signal output node and a source connected to a gain adjustment terminal at which a variable resistance element can be connected;
a fourth transistor having a gate connected to the output node of the Hall element, a drain connected to a drain of the third transistor, and a source connected to a ground node via fixed resistance resistor; and
a current source connected to the drains of the third and fourth transistors.

20. The semiconductor device according to claim 19, further comprising:
a fifth transistor connected in series with a sixth transistor between a first voltage terminal and a ground terminal, gates of the fifth and sixth transistors being connected to the voltage signal output node, the fifth and sixth transistors having different threshold voltages, an output voltage terminal being connected to a node between the fifth and sixth transistors.
